(19) United States
(12) Patent Application Publication
(10) Pub. No.: US 2014/0306293 A1
(43) Pub. Date: Oct. 16, 2014

(54) SEMICONDUCTOR MEMORY DEVICE INCLUDING GUARD BAND

(71) Applicant: Samsung Electronics Co., Ltd., Suwon-Si (KR)

(72) Inventors: Sang Hum BAEK, Hwaseong-si (KR); Hyuckjoon KWON, Yongin-si (KR)

(73) Assignee: SAMSUNG ELECTRONICS CO., LTD., Suwon-Si (KR)

(21) Appl. No.: 14/186,134

(22) Filed: Feb. 21, 2014

(30) Foreign Application Priority Data
Apr. 11, 2013 (KR) 10-2013-0039903

(51) Int. Cl. H01L 29/06; H01L 27/088

(52) U.S. Cl. CPC H01L 29/0619; H01L 27/088
USPC 257/394

(57) ABSTRACT

The semiconductor memory device including a first sense amplifier region including first metal-oxide-semiconductor (MOS) transistors disposed in a well on a semiconductor substrate, a second sense amplifier region adjacent to the well and including second MOS transistors disposed on the semiconductor substrate, a guard band having a bar type structure and provided between the first MOS transistors in the well, and a guard ring partially or fully enclosing the second sense amplifier region in the semiconductor substrate may be provided.

### CROSS-REFERENCE TO RELATED APPLICATIONS

This U.S. non-provisional patent application claims priority under 35 U.S.C. §119 to Korean Patent Application No. 10-2013-0039903 filed on Apr. 11, 2013, in the Korean Intellectual Property Office (KIPO), the entire contents of which are hereby incorporated by reference.

### BACKGROUND

The present disclosure herein relates to semiconductor devices including a guard band and/or a guard ring to reduce or prevent latch-up.

A bit line sense amplifier in a semiconductor memory device (e.g., a dynamic random access memory) is a circuitry which amplifies signal differences between bit lines in a bit line pair due to the so-called charge sharing operation between the bit lines.

As a semiconductor memory device becomes more highly integrated, influence of noise (e.g., latch-up) becomes larger. Therefore, various methods are being studied to reduce or prevent noise, for instance, in a sense amplifier circuitry.

Guard bands and/or guard rings may be disposed around metal-oxide-semiconductor (MOS) transistors in order to reduce or prevent latch-up between P-channel MOS (PMOS) transistors and N-channel MOS (NMOS) transistors in a sense amplifier.

### SUMMARY

The present disclosure provides a semiconductor memory device having a guard band and/or a guard ring disposed according to a method which reduces a chip size of the semiconductor device and reduces or prevents latch-up to enhance reliability.

According to example embodiments of the inventive concepts, a semiconductor memory device may include a first sense amplifier region including first metal-oxide-semiconductor (MOS) transistors disposed in a well on a semiconductor substrate, a second sense amplifier region adjacent to the well and including second MOS transistors disposed on the semiconductor substrate, a guard band having a bar type structure and provided between the first MOS transistors in the well, and a guard ring partially or fully enclosing the second sense amplifier region in the semiconductor substrate.

According to example embodiments, the guard band may have a bar type structure, and be disposed on the semiconductor substrate and interposed among the first MOS transistors disposed in the first sense amplifier region. The guard ring may be a ring type at least one of partially or fully enclosing the second sense amplifier region.

According to example embodiments, the guard ring may be a ring type enclosing the first sense amplifier region. The guard band may have a bar type structure, and be disposed on the semiconductor substrate and interposed among the second MOS transistors disposed in the second sense amplifier region.

According to example embodiments, a first guard band may have a bar type structure, and be disposed on the semiconductor substrate and interposed among the first MOS transistors disposed in the first sense amplifier region. A second guard band may have a bar type structure, and be disposed on the semiconductor substrate and interposed among the second MOS transistors disposed in the second sense amplifier region.

The semiconductor substrate, and sources and drains of the first MOS transistors may have a first conductive type, and the well, sources, and drains of the second MOS transistors may have a second conductive type.

The guard band may have the second conductive type, and the guard ring may have the first conductive type.

The first conductive type may be P-type and the second conductive type may be N-type.

A carrier density of the guard band may be higher than those of the well and the sources and drains of the second MOS transistors.

A carrier density of the guard ring may be higher than those of the semiconductor substrate, and the sources and drains of the first MOS transistors.

A step-up voltage may be applied to the guard band. A bulk bias voltage may be applied to the guard ring.

According to example embodiments, a semiconductor memory device may include a first circuitry region including first type of metal-oxide-semiconductor (MOS) transistors disposed in a well on a semiconductor substrate, a second circuitry region adjacent to the well and including second type of MOS transistors disposed on the semiconductor substrate, and a guard band having a bar type structure and provided at least one of between the first type of MOS transistors and between the second type of MOS transistors.

When the guard band is provided one of between the first type of MOS transistors included in the first circuitry region and between the second type of MOS transistors included in the second circuitry region, the semiconductor memory device may further include a guard ring partially or fully enclosing the other one of the first circuitry region and the second circuitry region in the semiconductor substrate.

The first circuitry region need not include the guard band and the guard ring in the well may partially or fully enclose the first circuitry region.

The second circuitry region may not include the guard band and the guard ring in the semiconductor substrate may enclose the second circuitry region.

The first type of MOS transistors may include sources and drains, the second type of MOS transistors may include sources and drain, the semiconductor substrate, and sources and drains of the first type of MOS transistors have a first conductive type, and the well, and sources and drains of the second type of MOS transistors have a second conductive type.

The guard band provided between the first type of MOS transistor may have the second conductive type, and the guard ring provided between the second type of MOS transistor may have the first conductive type.

The first conductive type may be P-type and the second conductive type may be N-type.

A carrier density of the guard band between the first type MOS transistors may be higher than those of the well and the sources and drains of the second type of MOS transistors.

A carrier density of the guard band between the second type MOS transistors may be higher than those of the semiconductor substrates, and the sources and drains of the first type of MOS transistors.

A carrier density of the guard ring enclosing the first circuitry region may be higher than those of the well and sources and drains of the second type of MOS transistors.

A carrier density of the guard ring enclosing the second circuitry region may be higher than those of the well, the semiconductor substrates, and the sources and drains of the first type of MOS transistors.

### BRIEF DESCRIPTION OF THE DRAWINGS

The accompanying drawings are included to provide a further understanding of the inventive concepts, and are incorporated in and constitute a part of this specification. The drawings illustrate example embodiments of the inventive concepts and, together with the description, serve to explain principles of the inventive concepts. In the drawings:

FIG. 1 illustrates a typical semiconductor memory device;

FIG. 2A illustrates a typical sense amplifier block;

FIG. 2B illustrates an example cross-sectional view taken along a line I-I′ of FIG. 2A;

FIG. 2C illustrates an example cross-sectional view taken along a line II-II′ of FIG. 2A;

FIG. 3 illustrates a sense amplifier block according to an example embodiment of the inventive concepts;

FIG. 4 illustrates a sense amplifier block according to another example embodiment of the inventive concepts; and

FIG. 5 illustrates a sense amplifier block according to still another example embodiment of the inventive concepts.

### DETAILED DESCRIPTION

Example embodiments will now be described more fully with reference to the accompanying drawings, in which some example embodiments are shown. Example embodiments, may, however, be embodied in many different forms and should not be construed as being limited to the embodiments set forth herein; rather, these example embodiments are provided so that this disclosure will be thorough and complete, and will fully convey the scope of example embodiments of inventive concepts to those of ordinary skill in the art. In the drawings, the thicknesses of layers and regions are exaggerated for clarity. Like reference numerals in the drawings denote like elements, and thus their description may be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof. Expressions such as “at least one of,” when preceding a list of elements, modify the entire list of elements and do not modify the individual elements of the list.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments. The regions illustrated in the figures are schematic in nature and their shapes are not intended to illustrate the actual shape of a region of a device and are not intended to limit the scope of example embodiments. It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

Hereinafter, example embodiments of the inventive concepts will be described in detail with reference to the accompanying drawings.

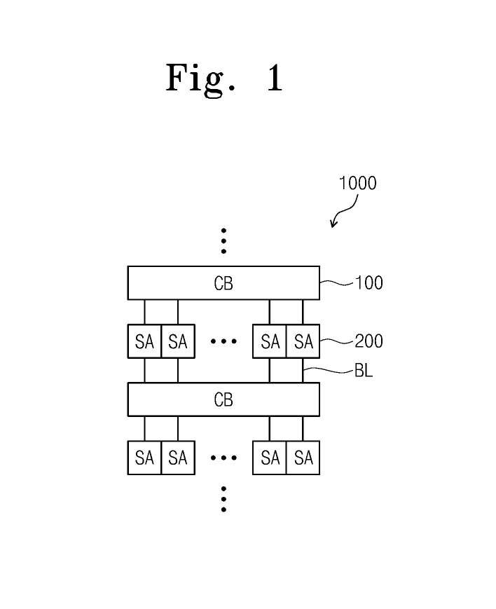

FIG. 1 illustrates a typical semiconductor device 1000. Referring to FIG. 1, the semiconductor memory device 1000 may include at least one cell block (CB) 100 and at least one sense amplifier block (SA) 200.

For example, the cell blocks 100 and the sense amplifier blocks 200 may be arranged in an alternating manner. The cell blocks 100 and the sense amplifier blocks 200 may be repetitively arranged along a direction in which bit lines (BL) extend. The sense amplifier block 200 amplifies and outputs data stored on memory cells.

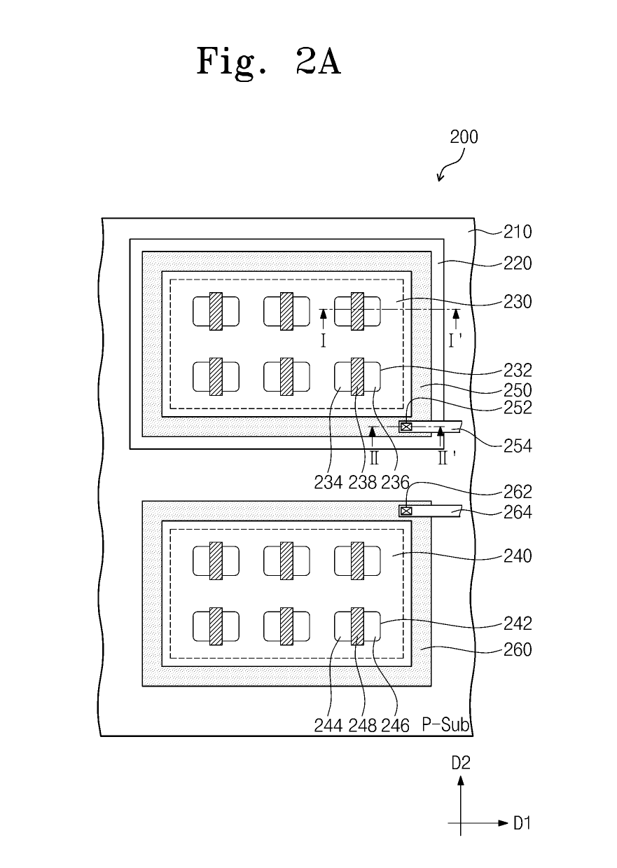

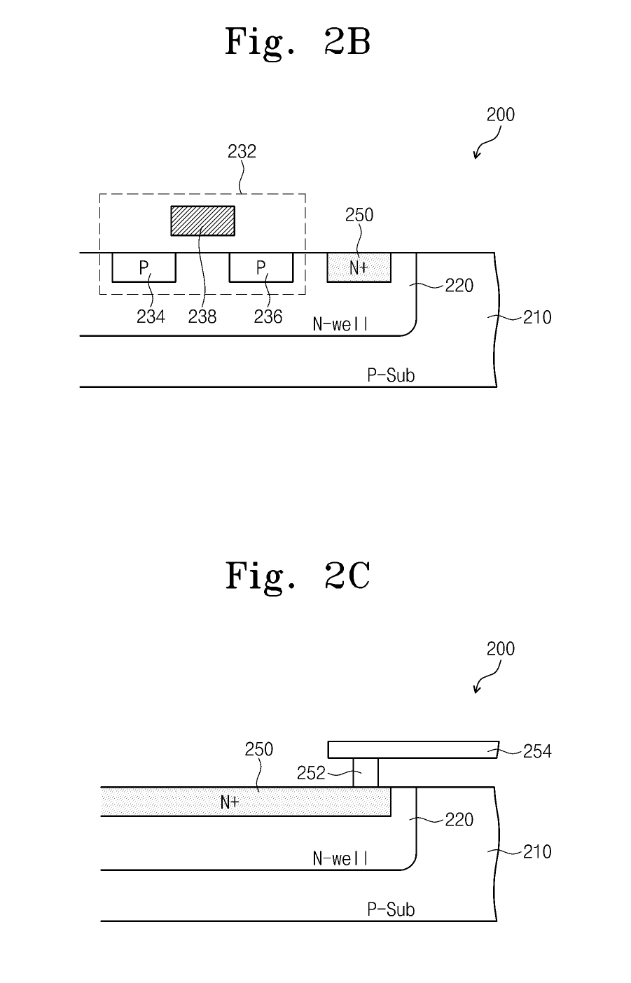

FIG. 2A illustrates a typical sense amplifier block 200. FIG. 2B is an example cross-sectional view taken along a line I-I′ of FIG. 2A, and FIG. 2C is an example cross-sectional view taken along a line II-II′ of FIG. 2A.

Referring to FIGS. 2A to 2C, a P-type sense amplifier region (P-SA) 230 may be disposed, for instance, in an N-well 220 on a P-type semiconductor substrate 210. The P-type sense amplifier region 230 may include a plurality of PMOS transistors 232. The PMOS transistor 232 may include a source 234, a drain 236, and a gate 238 doped with P-type impurity.

An N-type sense amplifier region (N-SA) 240 may be disposed on a P-type semiconductor substrate 210 adjacent to the P-type sense amplifier region 230. The N-type sense amplifier region 240 may include a plurality of NMOS transistors 242. The NMOS transistors 242 may include a source 244, a drain 246, and a gate 248 doped with N-type impurity.

An N-type guard ring 250 may be provided. The N-type guard ring 250 may have a ring type enclosing the P-type sense amplifier region 230 in an N-well 220.

A P-type guard ring 260 may be provided. The P-type guard ring 260 is adjacent to the N-well 220 and may have a ring type enclosing the N-type sense amplifier region 240 in the P-type semiconductor substrate 210.

In the case of a typical sense amplifier block 200, a step-up voltage V_{PP} is applied to the N-type guard ring 250 and a back bias voltage V_{BB} is applied to the P-type guard ring 260. In order to apply a bias voltage to the guard rings 250 and 260, a Vpp metal line 254 is provided to apply the step-up voltage V_{PP} to the N-type guard ring 260 through a contact 252, and a V_{BB} metal line 264 is provided to apply the back bias voltage V_{BB} to the P-type guard ring 260 through a contact 262. The V_{PP} metal line 254 and the V_{BB} metal 264 are typically arranged in parallel and to be adjacent to each other. As such, a V_{PP}/V_{BB} bridge phenomenon may occur due to deterioration of the metal lines.

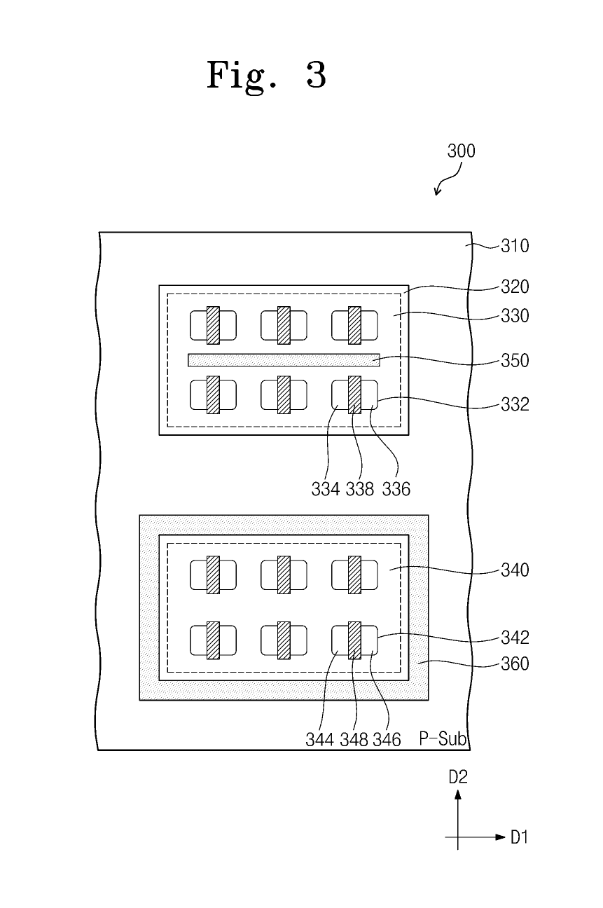

FIG. 3 illustrates a sensor amplifier block 300 according to an example embodiment of the inventive concepts. Hereinafter, repetitive description for the technical characteristics of the example embodiments described in relation to FIGS. 2A to 2C will be omitted and their differences will be described. Herein below, it is assumed that D1 direction is a first direction to which an input/output (I/O) line extends, and D2 direction is a second direction to which a bit line extends.

A first sense amplifier region 330 may be disposed in a well 320 on a semiconductor substrate 310. The first sense amplifier region 330 may include a plurality of first MOS transistors 332. Each of the first MOS transistors 332 may include a source 334, a drain 336, and a gate 338 doped with first conductive impurity.

A second sensor amplifier region 340 may be disposed on the first semiconductor substrate 310 and adjacent to the first sense amplifier region 330. A second sense amplifier region 340 may include a plurality of second MOS transistors 342. Each of the second MOS transistors 342 may include a source 344, a drain 346, and a gate 348 doped with second conductive impurity.

Like the guard ring 250 described in relation to FIGS. 2A to 2C, a guard band 350 may be disposed in the first sense amplifier region 330. The guard band may have a bar type structure, and be disposed in the D1 direction on the semiconductor substrate 310 and interposed among the first MOS transistors 332 which are disposed in the first sense amplifier region 330.

A guard ring 360 may be provided. As the guard ring 260 described in relation to FIGS. 2A to 2C, the guard ring 360 may be adjacent to the well 320 and may have a ring type enclosing the second sense amplifier region 340 on the semiconductor substrate 310.

The guard ring 360 and the semiconductor substrate 310 may have a first conductive type, the guard band 350 and the well 320 may have a second conductive type. For example, the first conductive type may be the P-type, and the second conductive type may be the N-type. A carrier density of the guard ring 350 may be higher than those of the well 320, and the sources 344 and drains 346 of the second MOS transistors 442. A carrier density of the guard ring 360 may be higher than those of the semiconductor substrate 310, and the sources 334 and drains 336 of the first MOS transistors 332.

Although FIG. 3 shows a case where a single guard band 350 is disposed in the D1 direction in the first sense amplifier region 330, example embodiments are not limited thereto. For example, a plurality of guard bands may be disposed in the first sense amplifier region 330.

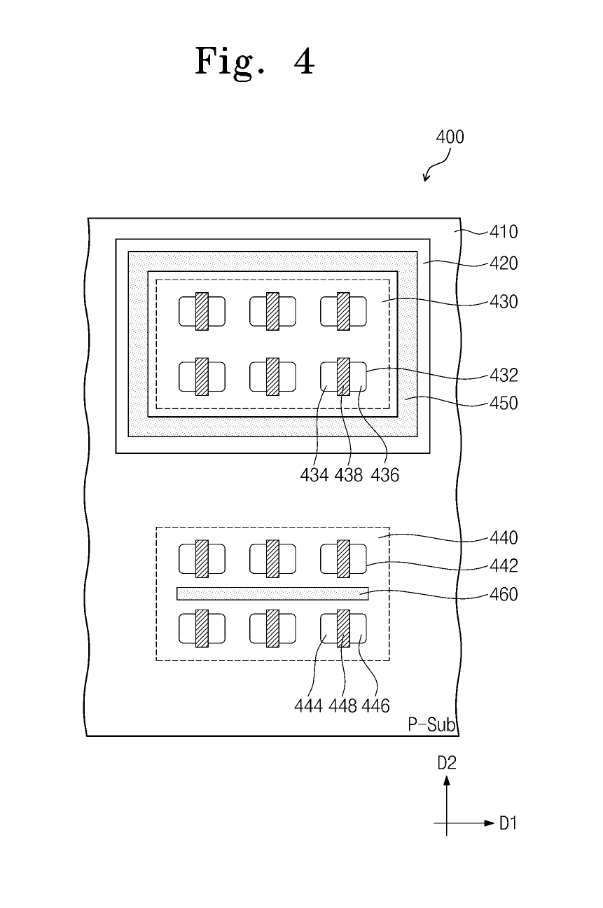

FIG. 4 illustrates a sense amplifier block 400 according to another example embodiment of the inventive concepts.

Referring to FIG. 4, a first sense amplifier region 430 may be disposed in a well 420 on a semiconductor substrate 410. The first sense amplifier region 430 may include a plurality of first MOS transistors 432. Each of the MOS transistors may include a source 434, a drain 436, and a gate 438 doped with a first conductive impurity.

A second sense amplifier region 440 may be disposed on the semiconductor substrate 410 and adjacent to the first sense amplifier region 430. A second sense amplifier region 440 may include a plurality of second MOS transistor 442. Each of the second MOS transistor 442 may include a source 444, a drain 446, and a gate 448 doped with a second conductive impurity.

A guard ring 450 may be provided. Like the guard ring 250 described in relation to FIGS. 2A to 2C, the guard ring 450 may have a ring type enclosing the first sense amplifier region 430 in the well 420.

Like the guard ring 260 described in relation to FIGS. 2A to 2C, a guard band 460 may be disposed in the second sense amplifier region 440. The guard band 460 may have a bar type structure, and be disposed in the D1 direction on the semiconductor substrate 410 and interposed between the second MOS transistors 442 (e.g., between neighboring groups of the second MOS transistors 442), which are disposed in the second sense amplifier region 440. Although FIG. 4 shows a case where the guard band has a bar type structure, example embodiments are not limited thereto. For example, the guard band may have any structures interposed between the second MOS transistors (e.g., a fishbone-like structure, a structure including a plurality of small bars disposed in one or more than one directions, a structure including a plurality of cross-like shapes, or a combination of those structures).

The guard band 460 and the semiconductor substrate 410 may have a first conductive type, and the guard ring 450 and the well 420 may have a second conductive type. For example, the first conductive type may be P-type and the second conductive type may be N-type. A carrier density of the guard ring 450 may be higher than those of the well 420, and the sources 444 and drains 446 of the second MOS transistors 442. A carrier density of the guard band 460 may be higher than those of the semiconductor substrate 410, and the sources 434 and the drains 436 of the first MOS transistors 432.

Although FIG. 4 shows a case where a single guard band 460 is disposed in the D1 direction in the second sense amplifier region 440, example embodiments are not limited thereto. For example, a plurality of guard bands may be disposed in the second sense amplifier region 440.

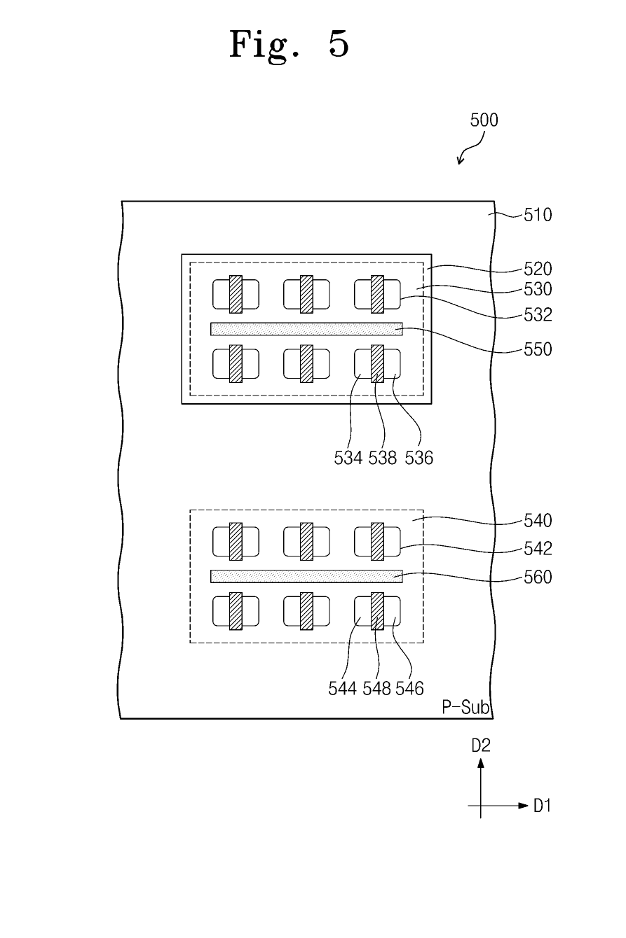

FIG. 5 illustrates a sense amplifier block 500 according to another example embodiment of the inventive concepts.

A first sense amplifier region 530 is disposed in a well 520 on a semiconductor substrate 510. The first sense amplifier region 530 may include a plurality of first MOS transistors 532. Each of the first MOS transistors 532 may include a source 534, a drain 536, and a gate 538 doped with first conductive impurity.

A second sense amplifier region 540 may be disposed on a first semiconductor substrate 510 and adjacent to the first sense amplifier region 530. The second sense amplifier region 540 may include a plurality of second MOS transistors 542. Each of the second MOS transistors 542 may include a source 544, a drain 546, and a gate 548 doped with second conductive impurity.

Like the guard ring 250 described in relation to FIGS. 2A to 2C, a first guard band 550 may be disposed in the first sense amplifier region 530. The first guard band 550 may have a bar type, and be disposed in the D1 direction on the semiconductor substrate 510 and interposed among the first MOS transistors 532 (e.g., between neighboring groups of the first MOS transistors 532), which are disposed in the first sense amplifier region 530.

Like the guard ring 260 described in relation to FIGS. 2A to 2C, a second guard band 560 may be disposed in the second sense amplifier region 540. The second guard band 560 may have a bar type, and be disposed in the D1 direction on the semiconductor substrate 510 and interposed among the second MOS transistors 542 (e.g., between neighboring groups of the second MOS transistors 542), which are disposed in the second sense amplifier region 540.

The second guard band 560 and the semiconductor substrate 510 may have a first conductive type, and the first guard band 550 and the well 520 may have a second conductive type. For example, the first conductive type may be P-type and the second conductive type may be N-type.

A carrier density of the guard band 550 may be higher than those of the well 520, and the sources 542 and drains 546 of the second MOS transistors 542. A carrier density of the second guard band 560 may be higher than those of the semiconductor substrate 510, and the sources 534 and the drains 536 of the first MOS transistors 532.

Although FIG. 5 shows a case where the first and second single guard bands 550 and 560 are disposed in the D1 direction in the first and second sense amplifier regions 530 and 540, respectively, example embodiments are not limited thereto. For example, a plurality of first guard bands and a plurality of second guard bands may be disposed in the first and second single sense amplifier regions 530 and 540.

Accordingly, when a bar type shaped guard band is disposed instead of a typical ring type guard ring, an area occupied by the first and/or second sense amplifier region can be reduced. Accordingly, if an area allotted for the sense amplifier block remains unchanged (e.g., the sense amplifier block occupies the same area as the existing one), the area to accommodate the first or second sense amplifier region can be enlarged as much as the reduction of an area occupied by the guard band and/or the guard ring, thereby improving circuit characteristics.

Furthermore, unlike the sense amplifier block of FIG. 2A in which the first and second ring type guard rings 250 and 260 are arranged adjacent to and in parallel with each other, the first and second guard bands 250 and 260 are arranged of the ring type are not disposed in parallel 250 and 260 of FIG. 2A, Accordingly, a V_{PP}/V_{BB} bridge phenomenon due to deterioration of the metal lines may be reduced or prevented.

Although a case where the guard band is disposed across the sense amplifier regions in the D1 direction is illustrated in this example embodiment example embodiments are not limited thereto. For example, the guard band may be also disposed in the D2 direction according to an interconnection method in the sense amplifier.

According to example embodiments of the inventive concepts, a guard band may be disposed between MOS transistors in a sense amplifier region, thereby reducing a size of a sense amplifier block and/or reducing or preventing latch-up.

Furthermore, a V_{PP}/V_{BB} bridge phenomenon, which may occur when guard rings of a typical ring type are disposed in parallel to each other, also can be reduced or prevented.

The above-disclosed subject matter is to be considered illustrative and not restrictive, and the appended claims are intended to cover all such modifications, enhancements, and other embodiments, which fall within the true spirit and scope of the inventive concepts. Thus, to the maximum extent allowed by law, the scope of the inventive concepts is to be determined by the broadest permissible interpretation of the following claims and their equivalents, and shall not be restricted or limited by the foregoing detailed description.

What is claimed is:

1. A semiconductor memory device comprising:
a first sense amplifier region including first metal-oxide-semiconductor (MOS) transistors disposed in a well on a semiconductor substrate;
a second sense amplifier region adjacent to the well and including second MOS transistors disposed on the semiconductor substrate;
a guard band having a bar type structure and provided between the first MOS transistors in the well; and
a guard ring at least one of partially and fully enclosing the second sense amplifier region in the semiconductor substrate.

2. The semiconductor memory device of claim 1, wherein the semiconductor substrate, and sources and drains of the first MOS transistors have a first conductive type, and the well, and sources and drains of the second MOS transistors have a second conductive type.

3. The semiconductor memory device of claim 2, wherein the guard band has the second conductive type, and the guard ring has the first conductive type.

4. The semiconductor memory device of claim 3, wherein the first conductive type is P-type and the second conductive type is N-type.

5. The semiconductor memory device of claim 1, wherein a carrier density of the guard band is higher than those of the well, and sources and drains of the second MOS transistors.

6. The semiconductor memory device of claim 1, wherein a carrier density of the guard ring is higher than those of the semiconductor substrate, and sources and drains of the first MOS transistors.

7. The semiconductor memory device of claim 1, wherein a step-up voltage is applied to the guard band.

8. The semiconductor memory device of claim 1, wherein a bulk bias voltage is applied to the guard ring.

9. A semiconductor memory device comprising:
a first circuitry region including first type of metal-oxide-semiconductor (MOS) transistors disposed in a well on a semiconductor substrate;
a second circuitry region adjacent to the well and including second type of MOS transistors disposed on the semiconductor substrate; and
a guard band having a bar type structure and provided at least one of between the first type of MOS transistors and between the second type of MOS transistors.

10. The semiconductor memory device of claim 9, further comprising:
when the guard band is provided one of between the first type of MOS transistors included in the first circuitry region and between the second type of MOS transistors included in the second circuitry region, a guard ring at least one of partially and fully enclosing the other one of the first circuitry region and the second circuitry region in the semiconductor substrate.

11. The semiconductor memory device of claim 9, wherein the first circuitry region does not include the guard band and the guard ring in the well encloses the first circuitry region.

12. The semiconductor memory device of claim 9, wherein the second circuitry region does not include the guard band and the guard ring in the semiconductor substrate encloses the second circuitry region.

13. The semiconductor memory device of claim 9, wherein
the first type of MOS transistors includes sources and drains,
the second type of MOS transistors includes sources and drain,
the semiconductor substrate, and sources and drains of the first type of MOS transistors have a first conductive type, and
the well, and sources and drains of the second type of MOS transistors have a second conductive type.

14. The semiconductor memory device of claim 13, wherein the guard band provided between the first type of MOS transistor has the second conductive type, and the guard ring provided between the second type of MOS transistor has the first conductive type.

15. The semiconductor memory device of claim 14, wherein the first conductive type is P-type and the second conductive type is N-type.

16. The semiconductor memory device of claim 13, wherein a carrier density of the guard band between the first type MOS transistors is higher than those of the well, and the sources and drains of the second type of MOS transistors.

17. The semiconductor memory device of claim 13, wherein a carrier density of the guard band between the second type MOS transistors is higher than those of the semiconductor substrates, and the sources and drains of the first type of MOS transistors.

18. The semiconductor memory device of claim 11, wherein a carrier density of the guard ring enclosing the first circuitry region is higher than those of the well, and sources and drains of the second type of MOS transistors.

19. The semiconductor memory device of claim 12, wherein a carrier density of the guard ring enclosing the second circuitry region is higher than those of the well, and the semiconductor substrates, and the sources and drains of the first type of MOS transistors.
